(19) United States
(12) Patent Application Publication
(10) Pub. No.: US 2005/0058311 A1
(43) Pub. Date: Mar. 17, 2005

(54) Stereo headphone

(76) Inventor: Lee Arthur Branom, Oceanside, CA (US)

Correspondence Address: LEE ARTHUR BRANOM, 1710 GALLATIN PL, OXNARD, CA, 93030, US

(21) Appl. No.: 10/662,486

(22) Filed: Sep. 15, 2003

(51) Int. Cl. H04R 5/02; H03G 5/00

(52) U.S. Cl. 381/309; 381/99; 381/384

(57) ABSTRACT

In a view of the foregoing disadvantages inherent in the known types of headphones now present in the prior art, the present invention provides an improved stereo headphone and a representative embodiment of the concepts of the present invention are illustrated in the drawing and makes use of two or more piezoelectric transducers 101, 102, and 103 with each transducer made for a specific frequency range and adapted to handle the high frequency mid frequency and low frequency ranges of the audio spectrum and a passive crossover network 104 which is utilized to properly manage the crossover frequencies which would facilitate the full spectrum of the audible frequency range and provide a new and improved stereo headphone.

### FIELD OF THE INVENTION

This invention relates in general to piezoelectric transducer technology and more especially to the usage of multiple piezoelectric transducers as well as crossover network configuration.

### BACKGROUND OF THE INVENTION

Speaker systems have utilized low frequency (bass), midrange frequency and high frequency (tweeter) speakers to provide a wide operating frequency range required to reproduce audio program material having a very wide frequency range. Such speaker systems have often relied on crossover networks to separate audio program material into low frequency, mid frequency and high frequency components for optimum reproduction by the bass, mid range, and high frequency speakers. Headphones are often relied upon to provide listening capability for portable radio frequency receivers. One piezoelectric transducer has often been used in such headphones to provide the frequency response necessary to present the audio program material. As a result there is no provision to handle separately the low frequency, mid frequency, and high frequency components of the audio program material, and often leads to a less than optimum wide frequency response from the headphones.

### BRIEF SUMMARY OF THE INVENTION

What is therefore needed is two or more piezoelectric transducers, each having a specific frequency range parameter which can provide high frequency mid frequency, and low frequency responses, and which would be coupled to a passive crossover network which has the capability to separate and produce the high, mid range, and low frequency components to provide a more responsive and wider frequency range in a stereo headphone.

### BRIEF DESCRIPTION OF THE DRAWING

FIG. 1 is a schematic diagram illustrating the piezoelectric transducers 101, 102, and 103 connected to the crossover network 104 of the present invention.

FIG. 2 is a facing view of the piezoelectric transducers 101, 102, and 103 as well as the crossover network 104 of FIG. 1 tipically positioned in one ear peice of a stereo headphone in accordance with the present invention.

FIG. 3 is a cross sectional view taken along line 3-3 of FIG. 2 in accordance with the present invention.

### DESCRIPTION OF THE PREFERRED EMBODIMENT

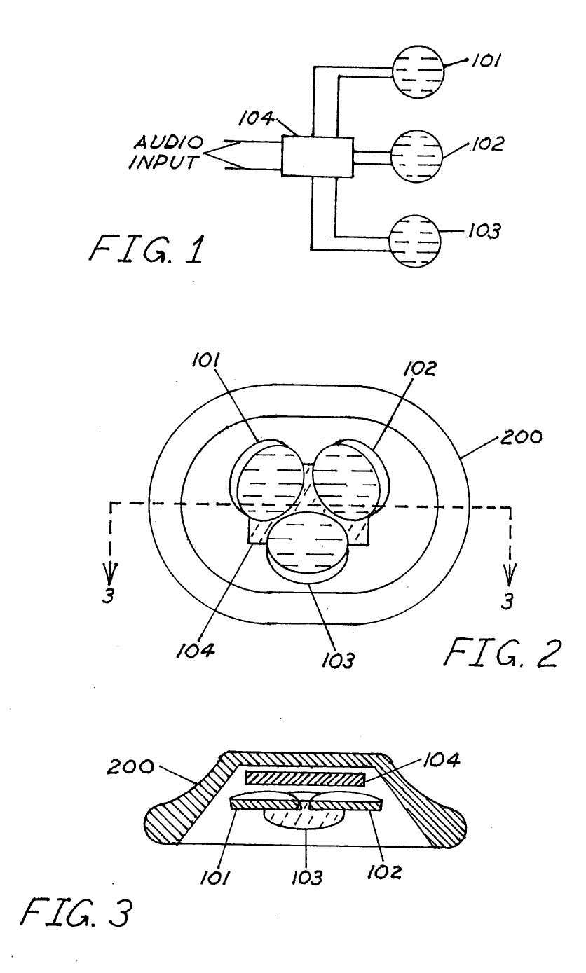

With reference now to FIG. 1 of the drawing and in particular to the piezoelectric transducers 101, 102, and 103 in accordance with the present invention. Using the piezoelectric transducer 101 which would be specifically designed and made to handle the high frequency response characteristics to provide implementation of the high frequency range of the present invention. In accordance with the present invention, piezoelectric transducer 102 would be specifically designed and made to provide for the responsibility of the mid range frequency response characteristics of the present invention and provide implementation of the mid frequency range. Piezoelectric transducer 103 is then specifically designed and made to handle the low frequency response characteristics and provide implementation of the low frequency range in accordance with the present invention.

Now with regard to the passive crossover network 104 as shown in FIG. 1 which is designed and made in accordance with the present invention and will properly handle and facilitate the crossover frequencies and totally manage the full spectrum of the audible frequency range to produce a wide frequency range high fidelity stereo headphone.

With reference now to FIG. 2 of the drawing where the three piezoelectric transducers 101, 102 and 103 tipically arranged in the ear peice enclosure 200 so the musical programming is not obstructed. The ear peice enclosure 200 can be manufactured using conventional techniques.

As may be seen in FIG. 3, the cross sectional view of the ear peice enclosure 200 taken along line 3-3 of FIG. 2, again we see the arrangement of the three piezoelectric transducers 101, 102, and 103 as well as the position of the crossover network 104 within the ear peice enclosure 200.

With respect to the above description then, the foregoing is considered as illustrative only of the principles of the invention. Further, since numerous modifications and changes will occur to those skilled in the art it is not desired to limit the invention to the exact construction shown and described, and accordingly, all suitable modifications and equivalents may be resorted to, falling within the scope of the invention.

1. A new and improved stereo headphone, comprising a multiple of two or more piezoelectric transducers in each ear piece with the two or more piezoelectric transducers of each piece working in conduction with each other in a stereo headphone.

2. The stereo headphone of claim 1, wherein each said piezoelectric transducer of each ear piece is designed and made to handle a specific part of the frequency range high, mid, and low ranges in a stereo headphone.

3. The stereo headphone of claim 2, wherein each said ear piece has a passive crossover network designed and made to facilitate the management of the high, mid, and low frequencies for each piezoelectric transducer in a stereo headphone.
